(19) United States
(12) Patent Application Publication
(10) Pub. No.: US 2019/0288170 A1
(43) Pub. Date: Sep. 19, 2019

(54) FLIP-CHIP PACKAGE

(71) Applicant: Soraa, Inc., Fremont, CA (US)

(72) Inventors: Scott West, Fremont, CA (US); Robert Harris, Fremont, CA (US); William Pickering, Fremont, CA (US)

(21) Appl. No.: 16/354,875

(22) Filed: Mar. 15, 2019

Related U.S. Application Data
(60) Provisional application No. 62/643,564, filed on Mar. 15, 2018.

(51) Int. Cl. H01L 33/62; H01L 33/60

(52) U.S. Cl. CPC H01L 33/62; H01L 33/60

(57) ABSTRACT

A flip-chip package comprising: (a) a lead frame; (b) a flip-chip LED defining a die footprint and having RDL contacts, the RDL contacts being configured to facilitate flip-chip mounting of the LED on the lead frame, each of the RDL contacts having a footprint greater than 20% of the die footprint; and (c) at least one bonding layer disposed between the RDL contacts and the lead frame package.

### REFERENCE TO RELATED APPLICATION

The present invention is based on U.S. Provisional Application No. 62/643,564, filed Mar. 15, 2018, hereby incorporated by reference in its entirety.

### FIELD OF INVENTION

The present invention relates, generally, to light-emitting diode (LED) flip-chip packaging, and, more specifically, to gallium nitride (GaN) LED flip-chip packages using lead frames.

### BACKGROUND

Lead frame packaging is desirable because of its low cost. However, Applicants have found that flip-chip packages are problematic due to (1) mismatches in the thermal expansion of the different materials used, (2) the relatively small area contact area between the lead frames and the die. Specifically, during thermal cycling of the package, the metal portions of the lead frames tend to move relative to each other. Although this does not present a problem ordinarily for wire bonded dies due to the compliance afforded by the wires themselves, flip chips are affixed directly to the metal portions. Therefore, any movement of the metal portions results in stress on the flip-chip die. Often the stress exceeds the bond shear strength of the flip-chip attachment to the metal portions, resulting in failure.

Therefore, there is a need for a flip-chip lead frame package that is resilient to the stress imparted by the metal portions of the lead frame during thermal cycling. The present invention fulfills this need among others.

### SUMMARY OF INVENTION

The following presents a simplified summary of the invention in order to provide a basic understanding of some aspects of the invention. This summary is not an extensive overview of the invention. It is not intended to identify key/critical elements of the invention or to delineate the scope of the invention. Its sole purpose is to present some concepts of the invention in a simplified form as a prelude to the more detailed description that is presented later.

As described above, the relative movement of metal portions of lead frame packages during thermal cycling and the small contacts associated with flip-chip dies, particularly LEDs, and more particularly GaN LEDs, often results in bond failure between the flip-chip die and the metal portions of the lead frame. These problems, however, have been addressed by the present invention.

In one embodiment, the invention relates to an LED package comprising: (a) a flip-chip LED, having a footprint and redistribution layer (RDL) contacts. The RDL contacts are configured to increase the size of the n contact and decrease the size of the p contact so as to facilitate flip-chip mounting of the LED on a lead frame. In one embodiment, each of the RDL contacts having a contact area greater than 20% of the footprint of the LED.

### BRIEF DESCRIPTION OF DRAWINGS

FIG. 1 shows a schematic side view of a flip-chip die of the present invention having a redistribution layer (RDL) configured for mounting to contacts on a lead frame.

FIG. 2A show a bottom view of RDL contact pads of one embodiment of the die of the present invention.

FIG. 2B shows the p and n contacts (i.e. epi layer contacts) of the die of FIG. 2a.

FIG. 3 shows one embodiment of the die package of the present invention disposed on a level 2 substrate.

FIGS. 4A and 4B illustrates how a smaller die reduces peak shear stress in one embodiment of the die package of the present invention.

FIG. 5 illustrates strain compensation in one embodiment of the die package of the present invention.

FIG. 6A shows a top view of another embodiment of the flip-chip package of the present invention that includes strain relief elements.

FIG. 6B shows a bottom view of the embodiment of FIG. 6A.

FIG. 6C shows a cross-sectional view of the embodiment of FIG. 6A.

FIG. 7 shows a schematic view of a flip chip die of the present invention having an RDL layer in combination with the lead frame.

FIGS. 8A and 8B compare two packages having thick and thin die attach stacks respectively.

### DETAILED DESCRIPTION

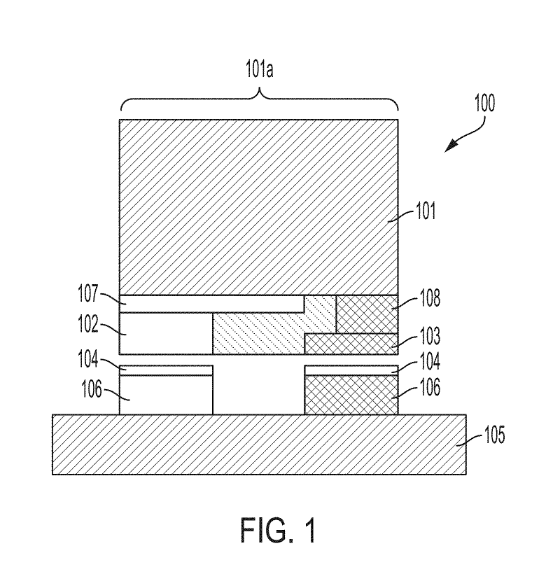

Referring to FIG. 1, one embodiment of a flip-chip package 100 of the present invention is shown. The flip-chip package 100 comprises a flip-chip LED 101, having a footprint 101a and redistribution layer (RDL) contacts 102, 103. The RDL p-contact 102, and n-contact 103 are configured to increase the size of the die-side n contact 108 and decrease the size of the die-side p contact 107 so as to facilitate flip-chip mounting of the LED on a lead frame 105. In one embodiment, each of the RDL contacts has a contact area greater than 20% of the footprint of the LED 101. The LED 101 is bonded to the lead frame 105 with a bonding layer 104, which comprises a non-compliant die attach material. In this particular embodiment, the lead frame 105 comprises columns 106 which extend upward and define a contact surface on which bonding layer 104 is disposed. In some embodiments, the die-side p-contact 107 has a footprint which is at least 50% (or 60%, 70%, 80%) of the total footprint of the die 101a.

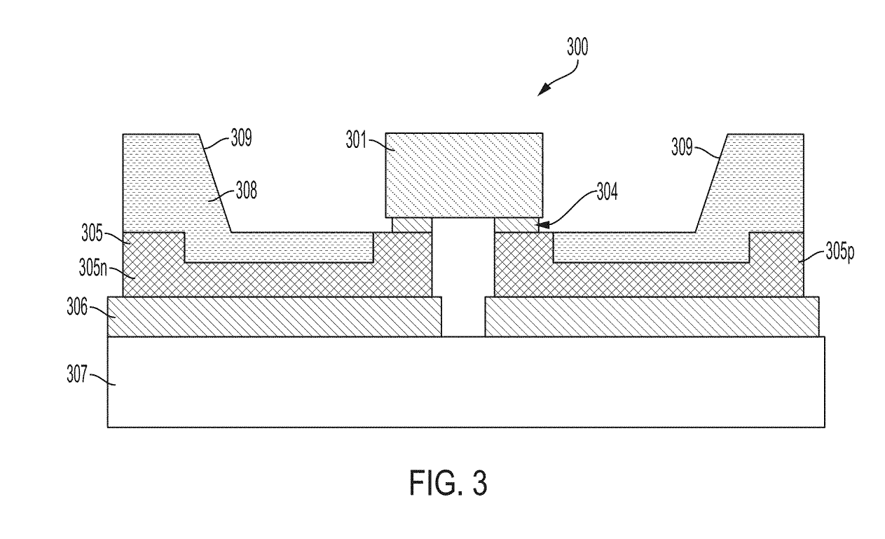

Referring to FIG. 3, one embodiment of the flip-chip package 300 of the present invention is shown. The flip-chip package 300 comprises an LED 301 having RDL contacts flip-chip mounted to the anode and cathode members 305n, 305p, respectively, of a lead frame 305. The LED 301 is bonded to the lead frame with a relatively thin, noncompliant bonding layer 304. The lead frame 305 is coupled to traces and pads 306 of a level 2 (L2) substrate 307. In one embodiment, the exposed area of the lead frame 305 (i.e. the area not covered by the flip-chip die) is overlayed with an insulating material 308. Such materials are generally well-known. In one embodiment, the insulating material is reflective. Suitable materials are known and include for example, EMC, SMC, or HMC (a hybrid of EMC and SMC). The reflective molding compound 308, in this particular embodiment, is molded into a cup defining sidewalls 309 to enhance the reflection of light from LED 301. The molding compound may be a white diffuser, such as a diffuser comprising TiO2 particles. It may have a reflectivity of at least 90% (or 80%, 95%) at a peak emission wavelength of the die. The molding compound may also be injected in-between the leadframe anode and cathode, although this is not shown on FIG. 3.

Without being tied to a particular theory, in one embodiment, the claimed invention involves a flip-chip package that is configured to drive stress downward, away from the die/lead frame interface and into the lead frame and L2 board. This is contrary to conventional configurations in which the LED package tends to accommodate stress through a compliant interface (e.g., a thick solder layer) between the die and the lead frame. In one embodiment, the flip-chip package of the present invention comprises one or more the following structural features for managing stress in the flip-chip package. It should be understood that the categorization of these features is for illustrative purposes only, and that the claims should, in no way, be limited by this categorization. Indeed, one of skill in the art will readily identify subcategories and/or cross/hybrid categories of the features in light of this disclosure.

A first feature of one embodiment of the flip-chip package of the present invention is a die having RDL contacts to expand the surface area of the n contact on the die. Conventional LED design typically involves minimizing the n contact of a die on the epi side to be to maximize light output. The RDL layer serves to expand the size of the n contact at the point that it mounts to the metal portion. (In addition to increasing the size of the n contact, the RDL layer also can increase the gap between the n and p contacts on the flip-chip die as shown in FIG. 1.) Applicants have found that increasing the size of the smaller n contact of the die reduces failure at the die/lead frame interface. For example, referring to FIG. 1, n contact 108 is significantly smaller than the p contact 107, however, the RDL n contact 103 is enlarged, and is more comparable in size to the RDL p contact 102. The LED 101 is bonded to the lead 105 with a bonding layer 104, which comprises a non-compliant die attach material. In this particular embodiment, the lead frame 105 comprises columns 106 which extend upward and define a contact surface on which bonding layer 104 is disposed

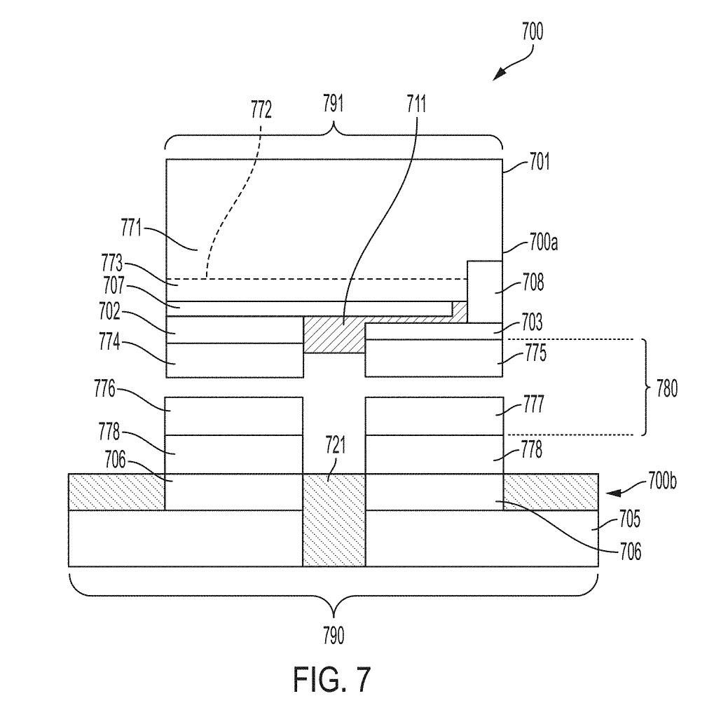

Referring to FIG. 7, a more detailed schematic of one embodiment of the flip-chip package 700 of the present invention is shown. More specifically, the flip-chip package 700 comprises flip-chip LED 700a mounted on a package 700b. The flip-chip LED 700a comprises a die 701 having an active region 772 between an n-GaN layer 771 and p-GaN layer 771. On the bottom of the die 701 are n and p contacts 707, 708. RDL p and n contacts 702, 703 are disposed on the p and n contacts 707, 708, respectively. These contacts may be metal stacks, and may comprise low-absorption metals (including, e.g., Ag or Al) and other metals selected for mechanical properties or to act as diffusion barriers (including, e.g., Ti, Al, Au, Ni, Pd, Pt, or Ag). As shown, the RDL n contact 703 is much larger than the n contact 708. Additionally, the distance between the RDL p and n contacts 702, 703 is significantly larger than the distance between the p and n contacts 707, 708. In this embodiment, an insulating material 771 (such as a dielectric) is disposed between p and n contacts. The insulating material may comprise, for example, SiN, SiOx, AlOx or TiOx, and combinations thereof, selected for their optical properties (including low absorption or transparency) and mechanical properties (including adhesion to materials, such as metals and semiconductors). Some layers of the insulating material may have a conformal shape and may be deposited by a technique facilitating conformality, including sputtering. Chip p and n pads 774, 775 are disposed on the RDL p and n contacts 702, 703, respectively. As discussed below, chip p and n pads, in one embodiment, comprise a strong bonding material, e.g., gold/tin alloy. The flip-chip LED package 700a defines a die footprint 791, which is the area defined by the perimeter of the flip chip LED package 700a.

Although the device shown in FIG. 7 has a simple epitaxial configuration with n-doped layers, active region and p-doped layers, it should be understood that multiple other layers known in the art may be included. The device may comprise a tunnel junction from p-material to n-material, such that both contacts (anode and cathode) are n-type contacts to n-type material.

The package 700b, in this embodiment, comprises a lead frame 705 (or metallic traces) and copper pillars 706 that extend upward from the lead frame 705 (or metallic traces). A layer of barrier material 778 is disposed on the copper pillars 706. Package p and n pads 776, 777 are disposed on the barrier metal layer 778. In this embodiment, the chip p and n pads 774, 775, and package p and n pads 776, 777 constitute the die attach stack 780 (or bonding layer). A reflector material 721 is disposed over the top surface of the package 700b. This reflector may comprise a diffuse reflector, or a specular reflector (including a metal, a dielectric stack, a combination thereof). The package 700b defines a package footprint 790, which is the area defined by the perimeter of the package 700b.

In one embodiment, each RDL contact is at least 20% of the footprint of the die, and, in a more particular embodiment, each RDL contact is at least 25% of the footprint of the die, and, in a still more particular embodiment, each RDL contact is at least 30% of the footprint of the die. Therefore, if each RDL contact is at least 20% of the footprint of the die and if the footprint is 250,000 μm², then each RDL contact is at least 50,000 μm².

In one embodiment, each RDL contact is sized to provide the minimum bond strength required for a given bonding material used. The bond strength quantifies the strength of the die-to-package interface in response to a shear stress. For instance, a bond strength of 100 g means that a force of 100 g is necessary to break the bond. (Bond strength depends upon a number of factors including the bonding material and the surface area of the bond.) In one embodiment, each RDL contact is at least 10,000 μm², and, in a more particular embodiment, each RDL contact is at least 25,000 μm², and, in the still more particular embodiment, each RDL contact is at least 50,000 μm². In one embodiment, each RDL contact has an area between 10,000 μm² and 150,000 μm², and, in a more particular embodiment, each RDL contact has an area between 25,000 μm² and 100,000 μm². In one embodiment, the sum of n contact surface area and p contact surface area is no less than 70% of the footprint, and, in a more particular embodiment no less than 80% of the footprint.

In one embodiment, the contact footprints are sufficiently large compared to the total footprint of the lead frame package. This may ensure that the die can resist the stress provided by the package. In some embodiments, the footprint of each of the RDL n- and p-contacts is at least 5%, (or at least 2%, or at least 10%, or at least 15%, or at least 20%) of the total package footprint.

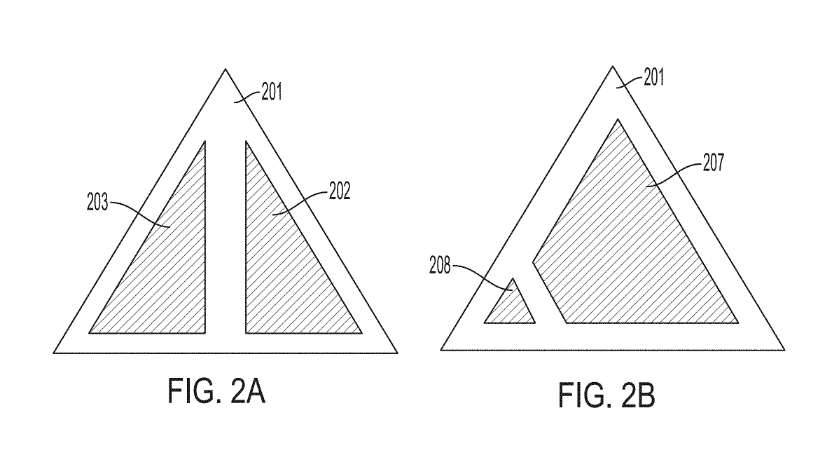

It should be understood that the shape of the contacts may vary, and that the RDL contacts are not necessarily square. For example, referring to FIG. 2A, triangular shaped RDL contacts are depicted. Still other shapes will be obvious to those of skill in the art in light of this disclosure.

In one embodiment, the distance between the anode and cathode members of the lead frame is minimized such that RDL contact size may be maximized. In other words, minimizing the space between the RDL contacts allows the RDL contacts to be as large as possible. The anode and cathode members of a conventional lead frame are separated by about 120-150 μm. Accordingly, in one embodiment, the flip-chip package comprises a lead frame having anode and cathode members separated by less than 150 μm, in a more particular embodiment, the members are separated by less than 100 μm, and, in still a more particular embodiment, the members are separated by less than 80 μm.

In one embodiment, the RDL contacts are configured such that the difference in surface area between the n and p contacts of the die is reduced. Again, without being tied to a particular theory, Applicants suspect that parity in contact size improves the structural integrity of the flip-chip package through thermal cycling. For example, in one embodiment, the RDL n contact surface area is at least 50% of the RDL p contact surface area, and, in a more particular embodiment, the RDL n contact surface area is at least 75% of the RDL p contact surface area. In one embodiment, the RDL n contact surface area is no greater than 200% of the RDL p contact surface area, and, in a more particular embodiment, is no greater than 150% of the RDL p contact surface area. In one embodiment, the ratio of the surface area of the RDL n contact to the RDL p contact is 0.5:1 to 2:1, and, in a more particular embodiment, 0.75:1 to 1.25:1.

A second feature of one embodiment of the flip-chip package of the present invention is a thin bond between the lead frame and the die that is a hard/noncompliant. This is contrary to conventional configurations in which the flip-chip mounted LED was typically bonded using a thick solder layer to afford compliance in the die bond, thus allowing the stresses between the L2 board and the lead frame package in the LED package to be transmitted through the interface of the die. Without being tied to a particular theory, Applicants suspect that the flip-chip package of the present invention does not accommodate strain at the die interface, but rather may form a rigid package, which directs the stresses downward, through the package and into the L2 board.

In one embodiment, the flip-chip package of the present invention comprises a bond layer comprising a hard/noncompliant material which holds the die rigidly to the lead frame to provide high bond strength. In other words, rather than configuring the bond for compliance, the bond of the present invention, in one embodiment, is configured for strength.

One of skill in the art will appreciate different ways to measure bond strength. Examples of bond strength may include, for example, shear strength, break strength, tensile strength, Young's Modulus, and shear v. flexural bond strength. As used herein, “interfacial shear strength” characterizes the strength of an interface before it breaks off. The failure in this case is at an interface (either die/solder or solder/package). As used herein “bulk shear strength” is the strength of a material against the type of yield or structural failure where the material or component fails in shear. As used herein, “bond strength” refers to bulk shear strength unless otherwise noted. If a device has multiple contact bonds, then “bond strength” pertains to the weakest contact bond, as it is likely to be the first point of failure.

In one embodiment, the bond strength is in the range of 50-500 g (or 80-200 g, or at least 50 g, or at least 80 g, or at least 100 g).

As mentioned above, the bonding layer comprises a noncompliant material. As used herein, the term “noncompliant” refers to a material having a bulk shear strength greater than 150 MPa. The noncompliant material may further have an elongation to break less than 25%. In one embodiment, the bonding layer material has a shear strength greater than 200 MPa, and, in a more particular embodiment, has a shear strength greater than 225 MPa. In one embodiment the bonding layer material has an elongation to break less than 10%, and, in a more particular embodiment, less than 5%. In one embodiment, the bonding layer material has a yield strength greater than 100 MPa (or 150 MPa, 200 MPa, 250 MPa).

Suitable bonding layer materials include, for example, gold/tin alloy. The alloy may be a eutectic. Noteworthy, the gold/tin mixture has a shear strength of 250 MPa, and an elongation to break of 2%. It should also be noted that the gold/tin mixture is a hard-eutectic material. Although, in one embodiment, a eutectic material is used as the boding material, it should be understood that the bonding layer material need not be a eutectic material, even though eutectic materials may be preferred/convenient for package assembly/preparation purposes.

Referring to Table 1 below, the properties of gold/tin alloy (AuSn) are compared to conventional solder (SAC305). Additionally, Table 1 discloses property values for the bonding material for one or more embodiments of the present invention. It should be understood that these property values can be found individually or in combination in bonding materials of the present invention. Further, the property values may be mixed and matched in any combination. In one embodiment, the bonding material has all of the property values.

TABLE 1

| Property | AuSn | | SAC305 | | Embodiments |
|---|---|---|---|---|---|
| Young's | 60-70 | GPa | 50 | GPa | At least 60 GPa |
| Modulus | | | | | |
| Shear | 25 | GPa | | | At least 20 GPa |
| Modulus | | | | | |
| Shear | 275 | MPa | 25 | MPa | At least 100 MPa |
| Strength | | | | | |
| Yield | 250 | MPa | 34 | MPa | At least 100 MPa |
| Strength | | | | | |
| Ultimate | 275 | MPa | 50 | MPa | At least 100 MPa |
| Tensile | | | | | |
| Strength | | | | | |
| Elongation | 2% | | 25-40% | | Less than 10% |
| to Break | | | | | |
| Possion's | 0.41 | | 0.36 | | At least 0.38 |
| Ratio | | | | | |
| CTE | 16.0 | PPM/deg C. | 21.5 | PPM/deg C. | Less than 19 |
| | | | | | PPM/deg C. |

The mechanical properties of the die-attach material may be combined with an appropriate thickness. In some embodiments, the hard die-attach material (or bonding layer) is relatively thin, which distinguishes embodiments from prior art where a tick (e.g. 25 um-200 um), compliant die-attach material is employed. Referring to FIG. 7, the thickness of the hard die attach material is defined as the sum of the chip-side pads and the package-side pads, since these two layers may react during the reflow step to form a hard AuSn eutectic. Thus, the thickness of the hard die-attach material is determined after the fabrication process. This hard die-attach material may be less than 10 um thick (or less than 15 um thick, or less than 8 um thick, or less than 5 um thick, or less than 3 um thick). In some embodiments, it is in a range 0.1-10 um. Further, some embodiments employ thin barrier metal layers to avoid/minimize deformation in the barrier layers. For example, the barrier metal layers may be in a range 0.1-10 um.

In some embodiments, the hardness properties ensuring a reliable package are provided by the chip- and package-side pads (i.e. referring to FIG. 7, AuSn layers 774-775 and Au layers 776-777, which after reflow may form an AuSn alloy). Other layers (such as the pads and barrier metals) may serve other purposes, including facilitating a good adhesion.

In some embodiments, having a thin die attach stack may be beneficial not only from a mechanical standpoint, but also from an optical standpoint. Indeed, the die attach stack may have limited reflectivity. Therefore, limiting its thickness may reduce optical loss.

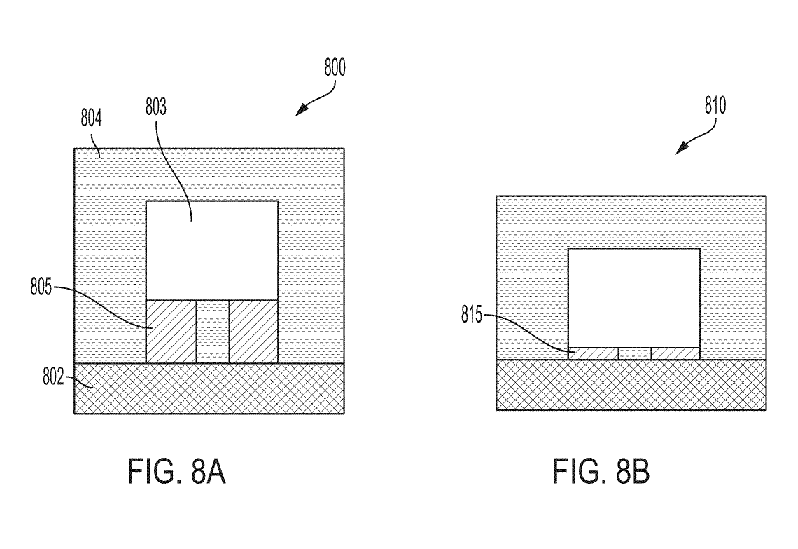

FIG. 8 shows a comparison of two package geometries. FIG. 8A shows an emitter 800 having a reflective package 802, a chip 803, a phosphor material 804 (for converting radiation from the chip) and a thick die attach 805. The die attach material may have a single-bounce optical absorption, averaged in the wavelength range 400-700 nm, of at least 10% (or at least 15%, 20%). Light (including pump and converted light) diffuses in the package and bounces several times (e.g. about 2 or 3 or 4 or 5 times on average) before escaping the package, such that this single-bounce optical loss is amplified. Since the die attach material is thick, the light is likely to impinge on it, resulting in a substantial net loss. In some cases, the net loss due to the thick die attach (defined as. the fraction of the total radiometric energy lost to absorption, divided by the electrical energy fed to the device) is at least 10%.

In contrast, FIG. 8B shows a package 810 having a thin die-attach material 815, according to some embodiments. In this case, the net loss caused by the die-attach stack may be less than 5% (or less than 2%, or less than 1%). Accordingly, embodiments may be characterized by a package efficiency of at least 80% (or at least 75%, or at least 80%, or at least 90%).

In some embodiments, the die-attach optical loss may also be mitigated by forming a reflective material over the die-attach stack. The reflective material may be a metal (formed by known techniques including evaporation, e-beam, sputtering, plating), or a diffusive reflector (formed by known techniques including jetting, wicking, spin-coating, wet dispense, curing). The reflective material may be formed before or after the die is attached. In some embodiments, the outer surface of the die-attach stack has a single-bounce optical absorption of less than 5% (or less than 2%).

In some embodiments, the device is characterized by a combination of a hard die-attach stack (characterized by bulk strength properties as discussed above, for instance yield strength) and strong die-attach interfaces (characterized by interfacial strength properties as discussed above, for instance bond strength)

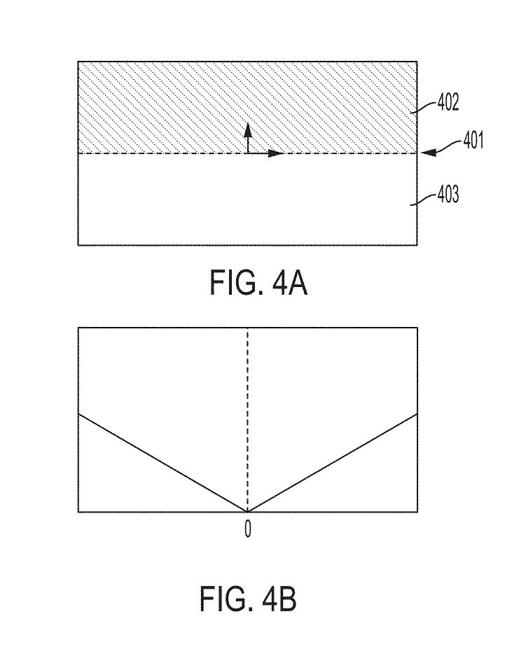

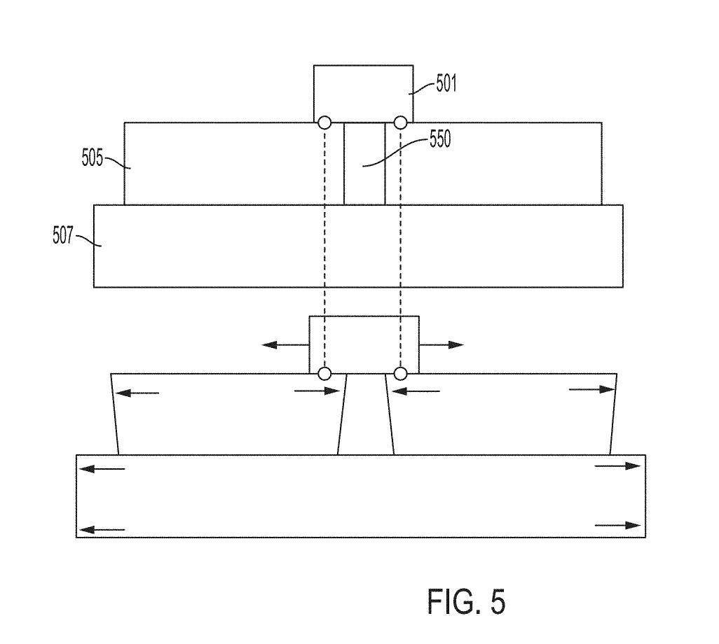

A third structural feature of one embodiment of the flip-chip package of the present invention is the use of a small die. Again, without being tied to a particular theory, Applicants suspect that a smaller die tends to reduce peak shear stress and to compensate for strain. More specifically, referring to FIG. 4A, thermal expansion mismatch causes shear stress to exist at the interface 401 between two materials 402, 403. Shear stress increases linearly with lateral distance x form the center of the interface as shown in FIG. 4B. A smaller interface will experience a lower peak stress. Thus, the bond of a small die will be subjected to less stress than that of a large die. Referring to FIG. 5, it is possible for the L2 substrate 507 and lead frame 505 to expand in such a way that their strains partially compensate one another in the vicinity of the lead frame gap 550. This phenomenon reduces the stress on the die 501/bonding layer material. This effect is most beneficial for a small die. Again, it should be understood that Applicant is somewhat speculating on the advantages of a smaller die, and the claimed invention should, in no way, be restricted by this speculation.

In one embodiment, the die of the present invention is smaller than a conventional flip-chip LED—i.e. less than 1 mm². In a more particular embodiment, the die has a footprint no greater than 250,000 μm², in yet a more particular embodiment, the die has a footprint no greater than 200,000 μm², (or greater than 150,000 μm² or greater than 100,000 μm²) and, in a still more particular embodiment, the die has a footprint between 50,000 μm² and 250,000 μm². In some embodiments the die has a triangular footprint, or a square footprint, with a lateral dimension less than 500 um (or less than 400 um).

A fourth feature of one embodiment of the flip-chip package of the present invention is a die configuration for providing a flip-chip package of high structural integrity and minimal stress points. More specifically, in one embodiment, the die is thick enough to ensure that it does not break prior to bond failure. In one embodiment, the die has a thickness of at least 10% of its lateral dimension, and, in a more particular embodiment, at least 20% of its lateral dimension. For example, if the die has a lateral dimension of 500 μm, then its thickness is at least 50 μm. Those of skill in the art will be able to optimize the thickness of the die in light of this disclosure. In some embodiments, the die comprises epitaxial layers and a portion of a substrate (such as a III-Nitride substrate or sapphire or SiC or Si or GaOx), and the substrate has a thickness of at least 10 um (or at least 20 um, or at least 30 um, or at least 50 um, or at least 100 um).

In addition to thickness, in one embodiment, the die is also configured to avoid acute angles, which not only result in undesirable current concentrations in the die, but also applicants suspect can become stress points in the die. Accordingly, in one embodiment, the angles of the die are at least 90 deg. The angles of the die are defined as the angles between the planes forming the surfaces of the die. Accordingly, the die may be a prism with a square shape, a hexagonal shape, or other shape having no acute angle.

A fifth feature of one embodiment of the flip-chip package of the present invention is compliance in the lead frame configuration. Again, without being bound to any particular theory, the flip-chip package of the present invention tends to drive stresses away/downward from the flip-chip die and the die's interface with the lead frame. To this end, in one embodiment, the flip-chip package provides compliance below the die/lead frame interface. In one embodiment, this compliance is provided by copper pillars extending upward from the lead frame. For example, referring to FIG. 1, in one embodiment, copper pillars 106 extend upward from the lead frame 105. Applicants suspect that if the pillars are adequately high, they provide some degree of compliance through the thermal cycling of the die package 100. Although one skilled in the art determine an optimum height of the pillars with undue experimentation, applicants have found that pillars heights of 20 to 200 μm have provided suitable results. In some embodiments, the copper pillars are characterized by an aspect ratio of their lateral size divided by their height. The aspect ratio may be in the range of ½-2 (or ⅓-3 or ⅕-5).

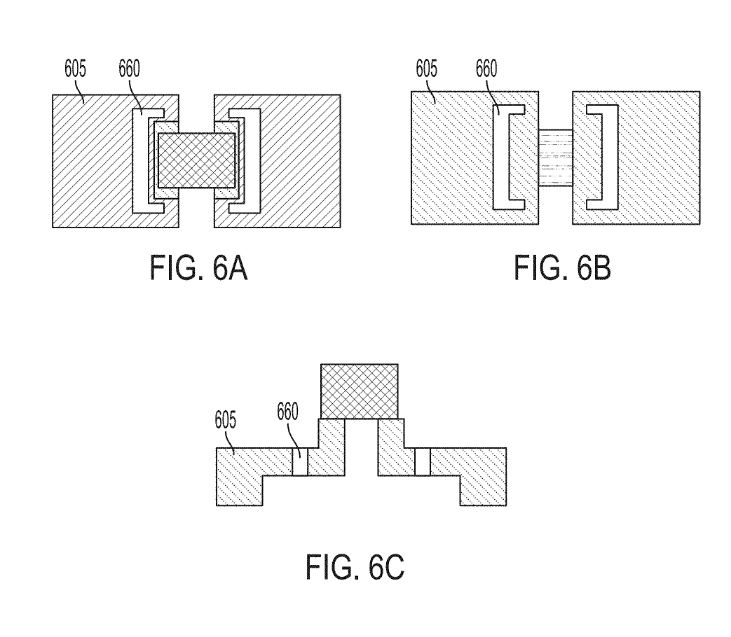

In some embodiments, strain relief structures are provided. These may be openings in the metal body in the lead frame, which separate the area where the LED is attached from the rest of the lead frame metal body. Thus, thermal expansion of the metal body may not lead to much strain at the die level. FIGS. 6A-6C show an embodiment of the flip-chip package of the present invention that includes strain relief structures in the form of openings 660 in the metal body of the lead frame 605.

The flip-chip package of the present invention is particularly useful at high power densities (where thermal expansion becomes more of an issue). For example, the flip-chip package of the present invention is suitable for input electrical power of at least 100 mW, 500 mW, 1 W, 2 W, 3 W, or 5 W.

Having thus described a few particular embodiments of the invention, various alterations, modifications, and improvements will readily occur to those skilled in the art. Such alterations, modifications, and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

What is claimed is:

1. A flip-chip package comprising:
a lead frame;
a flip-chip LED defining a die footprint and having RDL contacts, said RDL contacts being configured to facilitate flip-chip mounting of said LED on said lead frame, each of said RDL contacts having a footprint greater than 20% of said die footprint; and
at least one bonding layer disposed between said RDL contacts and said lead frame package.

2. The flip-chip package of claim 1, wherein said RDL contacts comprise an RDL p contact and an RDL n contact, said RDL n contact having an RDL n contact footprint and said RDL p contact having an RDL p contact footprint, said RDL n contact footprint being at least 50% of said RDL p contact footprint.

3. The flip-chip package of claim 2, wherein the ratio of said RDL n contact footprint to said RDL p contact footprint is 0.5:1 to 2:1.

4. The flip-chip package of claim 2, wherein the sum of said RDL n contact footprint and said RDL p contact footprint is no less than 70% of the die footprint.

5. The flip-chip package of claim 1, wherein each RDL contact footprint is at least 25% of the die footprint.

6. The flip-chip package of claim 1, wherein each RDL contact footprint is at least 10,000 μm².

7. The flip-chip package of claim 6, wherein each RDL contact footprint is between 25,000 μm² and 100,000 μm².

8. The flip-chip package of claim 1, wherein the lead frame has anode and cathode members separated by less than 100 μm.

9. The flip-chip package of claim 1, wherein said at least one bonding layer has a thickness no greater than 10 um.

10. The flip-chip package of claim 1, wherein said at least one bonding layer comprising a non-compliant die attach material.

11. The flip-chip package of claim 10, wherein said non-compliant die attach material has a bulk shear strength greater than 150 MPa.

12. The flip-chip package of claim 10, wherein said non-compliant die attach material has a yield strength greater than 100 MPa.

13. The flip-chip package of claim 10, wherein said non-compliant die attach material comprises a gold/tin alloy.

14. The flip-chip package of claim 1, wherein said die footprint is no greater than 250,000 um2.

15. The flip-chip package of claim 1, wherein said flip-chip LED has a lateral dimension less than 500 um

16. The flip-chip package of claim 1, wherein said flip-chip LED has a thickness of at least 10% of its lateral dimension.

17. The flip-chip package of claim 1, wherein said lead frame comprises anode and cathode members and metallic pillars extending upward from said anode and cathode members, said metallic pillars being configured for electrical connection to said RDL contacts.

18. The flip-chip package of claim 17, wherein said metallic pillars extend 20 to 200 μm upward from said anode and cathode members.

19. The flip-chip package of claim 17, wherein said metallic pillars copper pillars define an aspect ratio of their maximum width divided by their height, said aspect ratio being in the range of ½ to 2.

20. The flip-chip package of claim 17, wherein a reflective material covers said anode and cathode members and surrounds said metallic pillars.
